(19) United States
(12) Patent Application Publication
(10) Pub. No.: US 2025/0219599 A1
(43) Pub. Date: Jul. 3, 2025

(54) GAIN PERFORMANCE CIRCUIT

(71) Applicant: SKYWORKS SOLUTIONS, INC., Irvine, CA (US)

(72) Inventors: Anthony Francis QUAGLIETTA, Methuen, MA (US); Duncan LITTLE, Tyngsborough, MA (US)

(21) Appl. No.: 19/004,144

(22) Filed: Dec. 27, 2024

Related U.S. Application Data
(60) Provisional application No. 63/616,141, filed on Dec. 29, 2023.

(51) Int. Cl. H03F 3/213

(52) U.S. Cl. CPC H03F 3/213; H03F 2200/451

(57) ABSTRACT

A power amplifier circuit comprising a first transistor having a first collector, a first emitter, and a first base, a second transistor having a second collector, a second emitter, and a second base, the second transistor being thermally linked to the first transistor and a bias transistor having a third collector, a third emitter, and a third base, the bias transistor being coupled between the first transistor and the second transistor.

### CROSS-REFERENCE TO RELATED APPLICATION(S)

This application claims priority to U.S. Provisional Application No. 63/616,141 filed Dec. 29, 2023, entitled GAIN VS. TIME PERFORMANCE CIRCUIT, the disclosure of each of which is hereby expressly incorporated by reference herein in its respective entirety.

### BACKGROUND

### Field

The present disclosure relates to amplifier devices.

### Description of the Related Art

When an amplifier is turned on, the active amplification devices within the amplifier turn on and hence some level of self-heating of the amplifier is realized such that a temperature at and/or around the amplifier may increase. In some cases, an amplifier may have multiple amplification stages which may each experience some level of self-heating. This ‘self-heating’ effect may result in a decrease of gain of the amplifier and/or gain variation over time which may cause degradation of the error vector magnitude (EVM) of the amplifier (which is a measure of linearity). For amplifiers that are pulsed and are used in modulated systems (e.g., with peak-to-average signals), the gain variation over time may be even further degraded, which may result in a degraded dynamic EVM (DEVM). EVM degradation for a 4 ms pulse has been shown to be directly related to gain decrease over the pulse width.

### SUMMARY

In some implementations, the present disclosure relates to a power amplifier circuit including: a first transistor having a first collector, a first emitter, and a first base; a second transistor having a second collector, a second emitter, and a second base, the second transistor being thermally linked to the first transistor; and a bias transistor having a third collector, a third emitter, and a third base, the bias transistor being coupled between the first transistor and the second transistor.

In some aspects, the techniques described herein relate to a circuit wherein the first transistor includes a first stage of the circuit and the second transistor includes a second stage of the circuit.

In some aspects, the techniques described herein relate to a circuit wherein the first transistor and the second transistor are disposed less than 10 μm away from each other.

In some aspects, the techniques described herein relate to a circuit wherein first collector and the third base are coupled at a first node.

In some aspects, the techniques described herein relate to a circuit wherein the first collector is directly coupled to the third base.

In some aspects, the techniques described herein relate to a circuit wherein the third emitter is coupled to the second base.

In some aspects, the techniques described herein relate to a circuit wherein the third emitter is coupled to the second base via a first resistor.

In some aspects, the techniques described herein relate to a circuit wherein the third collector is coupled to a first voltage source.

In some aspects, the techniques described herein relate to a circuit wherein the first base and the third base are coupled to a first voltage source.

In some aspects, the techniques described herein relate to a circuit wherein the second collector is coupled to a first voltage source.

Some implementations of the present disclosure relate to a semiconductor die of a power amplifier including: a first transistor having a first collector, a first emitter, and a first base; a second transistor having a second collector, a second emitter, and a second base, the second transistor being thermally linked to the first transistor; and a bias transistor having a third collector, a third emitter, and a third base, the bias transistor being coupled between the first transistor and the second transistor.

In some aspects, the techniques described herein relate to a semiconductor die wherein the first transistor includes a first stage of the power amplifier and the second transistor includes a second stage of the power amplifier.

In some aspects, the techniques described herein relate to a semiconductor die wherein the first transistor and the second transistor are disposed less than 10 μm away from each other.

In some aspects, the techniques described herein relate to a semiconductor die wherein first collector and the third base are coupled at a first node.

In some aspects, the techniques described herein relate to a semiconductor die wherein the first collector is directly coupled to the third base.

In some aspects, the techniques described herein relate to a semiconductor die wherein the third emitter is coupled to the second base.

In some aspects, the techniques described herein relate to a semiconductor die wherein the third emitter is coupled to the second base via a first resistor.

In some aspects, the techniques described herein relate to a semiconductor die wherein the third collector is coupled to a first voltage source.

In some aspects, the techniques described herein relate to a semiconductor die wherein the first base and the third base are coupled to a first voltage source.

In some aspects, the techniques described herein relate to a semiconductor die wherein the second collector is coupled to a first voltage source.

### BRIEF DESCRIPTION OF THE DRAWINGS

FIG. 1 depicts a system that includes a wearable audio device in communication with a host device.

FIG. 2 illustrates an example circuit of a power amplifier in accordance with one or more examples.

FIG. 3 illustrates an example circuit of a power amplifier without thermal tracking.

FIG. 4 illustrates an example circuit of a power amplifier with thermal tracking in accordance with one or more examples.

FIG. 5 provides a diagram illustrating a first array and/or a second array which may not be thermally linked.

FIG. 6 provides a diagram illustrating a first array and/or a second array which may be thermally linked.

FIG. 7 illustrates an example circuit of a power amplifier in accordance with one or more examples.

FIG. 8 illustrates an example packaged module.

FIG. 9 depicts an example wireless device having one or more advantageous features described herein.

### DETAILED DESCRIPTION OF SOME EMBODIMENTS

The headings provided herein, if any, are for convenience only and do not necessarily affect the scope or meaning of the claimed invention.

The present disclosure relates to amplifier devices.

When an amplifier is turned on, the active amplification devices within the amplifier turn on and hence some level of self-heating of the amplifier is realized such that a temperature at and/or around the amplifier may increase. In some cases, an amplifier may have multiple amplification stages which may each experience some level of self-heating. This ‘self-heating’ effect may result in a decrease of gain of the amplifier and/or gain variation over time which may cause degradation of the error vector magnitude (EVM) of the amplifier (which is a measure of linearity). For amplifiers that are pulsed and are used in modulated systems (e.g., with peak-to-average signals), the gain variation over time may be even further degraded, which may result in a degraded dynamic EVM (DEVM). EVM degradation for a 4 ms pulse has been shown to be directly related to gain decrease over the pulse width.

Some general mobile power amplifiers may not be suitable for use with controllers that can shape the bias versus time to compensate for self-heating of transistors. Gallium arsenide (GaAs) power amplifiers in particular may not be capable of supporting complex bias circuits to offset gain roll-off versus time. Passive circuits requiring no analog processing can help compensate for the gain roll-off versus time.

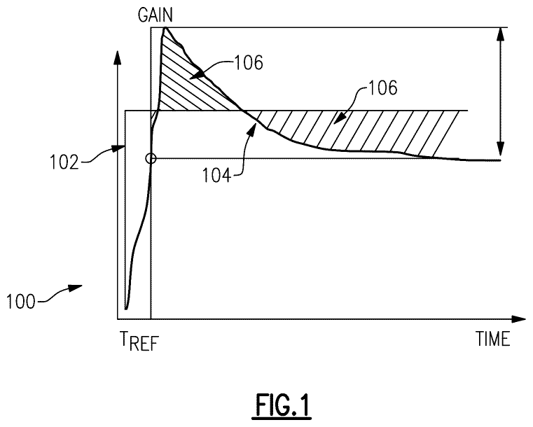

FIG. 1 illustrates a comparison graph 100 showing an ideal gain plot and a practical gain plot. A first plot 102 provides ideal gain performance: when the amplifier is turned on, the ideal amplifier immediately reaches a peak gain value and maintains the peak gain value indefinitely. In comparison, a second plot 104 provides an example of practical gain performance: when the amplifier turns on, there is a period of delay before the amplifier ramps up to a peak gain value and gradually decreases from the peak gain value over time. Practical gain performance as illustrated by the second plot 104 creates various instances of error 106, or in other words, differences from the ideal gain performance. Error 106 is measured in FIG. 1 beyond a “tref” (e.g., beginning of preamble) point. It is advantageous to minimize the error as much as possible for an amplifier.

Some embodiments described herein provide devices and/or methods for reducing gain error. In some embodiments, a circuit for a power amplifier may be configured to self-correct and/or otherwise respond to heating at an amplifier network of the power amplifier. Moreover, a power amplifier may include various devices configured to detect heating at and/or near the amplifier network. Responses to heating may be performed automatically in response to detected heating. Some embodiments may be configured for use with multi-stage (e.g., two or more amplification stages) while some embodiments may be configured for use with single-stage amplifiers as well or alternatively.

Power amplifier turn-on characteristics can suffer from undesirable gain versus time (GvT) non-linear behavior that can result in reduced system level EVM performance. Some embodiments described herein can provide methods and/or systems for advantageously reducing GvT non-linear performance degradation.

Embodiments described herein can comprise power amplifier semiconductor dies configured to improve PvT performance. In some examples, compensation circuitry external to the power amplifier die may not be required.

In some embodiments, bias circuit reference devices of a power amplifier may be utilized to maximize heat transfer between a radio frequency (RF) array and the bias circuit reference device(s). RF device to reference device thermal interaction may be manipulated to control a GvT response of the power amplifier.

Some embodiments minimize emitter-to-emitter spacing between an RF device and/or array and a reference device of a power amplifier to speed up and/or increase thermal sharing between the RF device and/or array and the reference device (e.g., bias circuit). Such a configuration can achieve improved GvT performance (e.g., an approximately forty percent reduction in GvT excursion over a 4 ms burst). Moreover, embodiments described herein can require less quiescent current and/or can provide increased power-added efficiency.

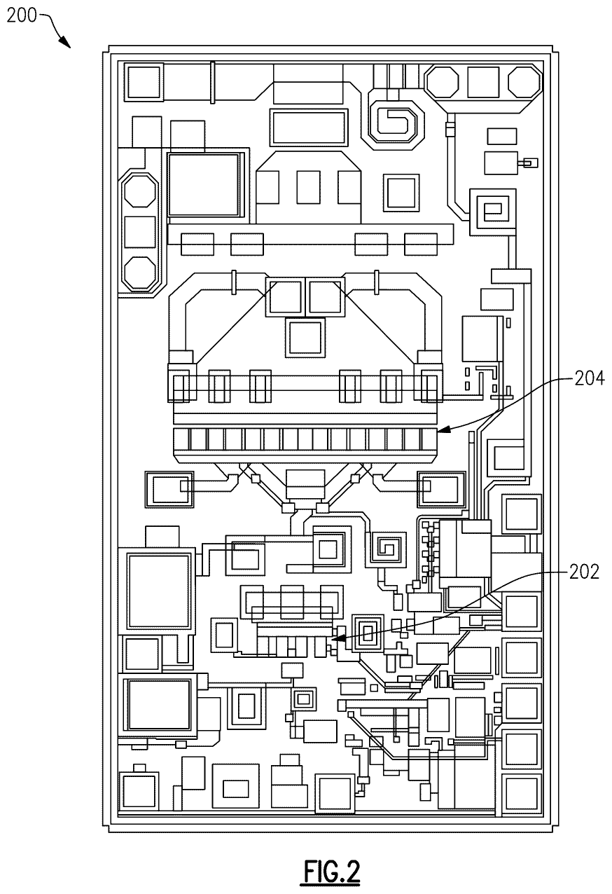

FIG. 2 illustrates an example circuit 200 of a power amplifier in accordance with one or more examples. The circuit 200 may comprise a single semiconductor die. In some examples, the circuit 200 may comprise a first array 202 and/or a second array 204. The first array 202 and/or second array 204 may comprise one or more RF devices (e.g., negative-positive-negative (NPN) transistors). In some examples, the first array 202 and the second array 204 may be disposed at different stages of a power amplifier. For example, the first array 202 may comprise stage two of a power amplifier and/or the second array 204 may comprise stage three of the power amplifier. The first array 202 and/or second array 204 may comprise single-collector RF end devices. This may advantageously allow the first array 202 and second array 204 to be situated as closely as possible to one another to create a thermal link between the first array 202 and the second array 204 and/or to improve gain vs. time of the power amplifier.

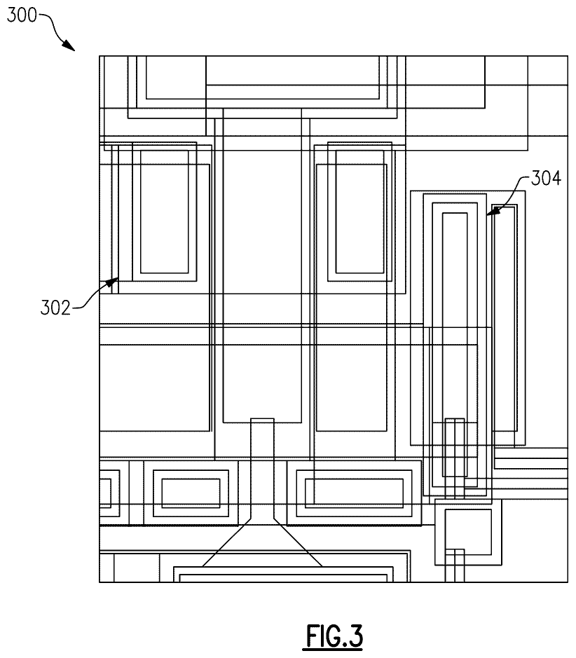

FIG. 3 illustrates an example circuit 300 of a power amplifier without thermal tracking. The circuit 300 may comprise a first array 302 and/or a second array 304 that may be sufficiently distanced apart to prevent thermal tracking and/or linking between the first array 302 and the second array 304.

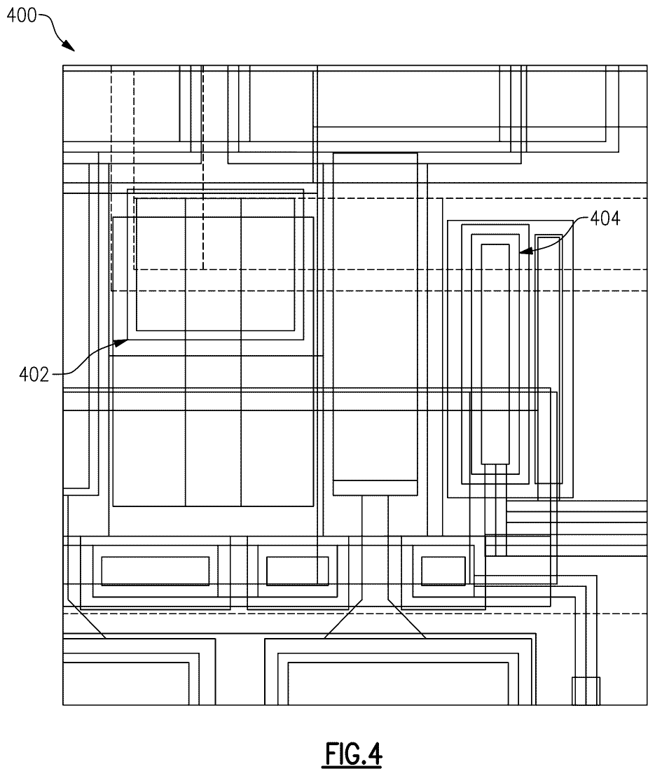

FIG. 4 illustrates an example circuit 400 of a power amplifier with thermal tracking in accordance with one or more examples. The circuit 400 may comprise a first array 402 and/or a second array 404 that may be sufficiently close together to allow thermal tracking and/or linking between the first array 402 and the second array 404.

FIG. 5 provides a diagram illustrating a first array 502 and/or a second array 504 which may not be thermally linked. The first array 502 may comprise one or more devices and/or the second array 504 may comprise one or more devices. There may exist a relatively large (e.g., approximately 18 μm) distance separating the first array 502 and the second array which may prevent thermal coupling between the first array 502 and the second array 504.

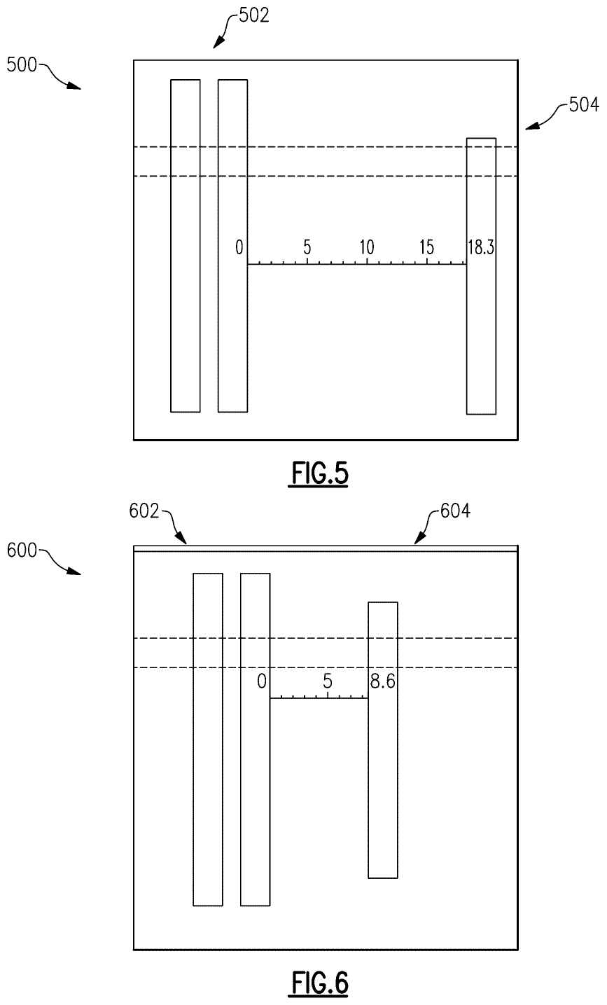

FIG. 6 provides a diagram illustrating a first array 602 and/or a second array 604 which may be thermally linked. The first array 602 may comprise one or more devices and/or the second array 604 may comprise one or more devices. There may exist a relatively small (e.g., approximately 8.6 μm) distance separating the first array 602 and the second array which may allow thermal coupling between the first array 602 and the second array 604.

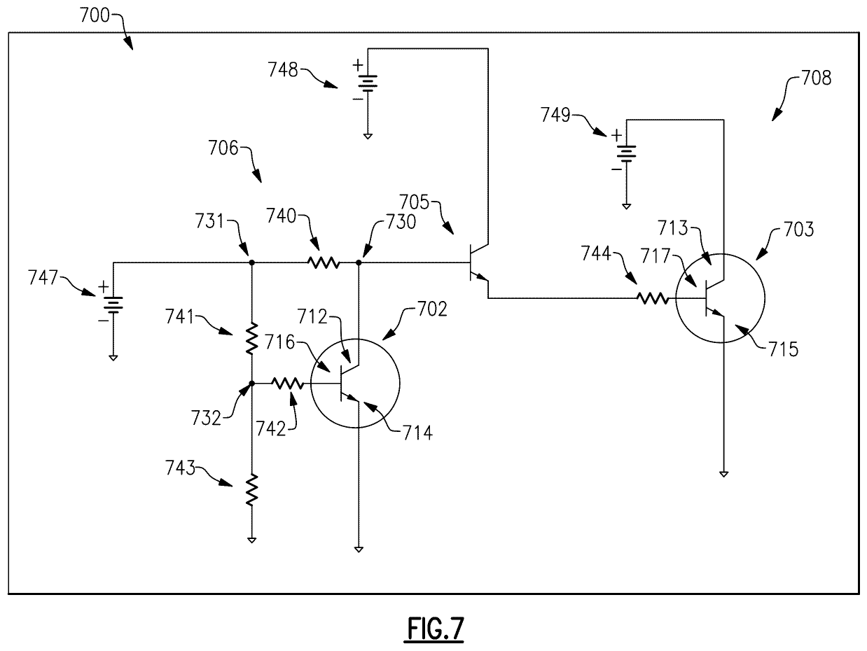

FIG. 7 illustrates an example circuit 700 of a power amplifier in accordance with one or more examples. The circuit 700 may comprise a single semiconductor die. In some examples, the circuit 700 may comprise a first device 702 and/or array and/or a second device 704 and/or array. The first device 702 and/or second device 704 may comprise RF bipolar NPN transistors. In some examples, the first device 702 and the second device 704 may be disposed at different stages of a power amplifier. For example, the first device 702 may be disposed at a first stage 706 of the power amplifier and the second device 704 may be disposed at a second stage 708 of the power amplifier. In some examples, the first device 702 and the second device 704 may be thermally coupled. For example, the first device 702 and the second device 704 may be separated by less than 10 μm.

The first device 702 may comprise a first collector 712, a first emitter 714, and/or a first base 716. The first emitter 714 may be grounded and/or coupled to ground. The first collector 712 may be directly coupled to a first node 730. The first node 730 may be coupled to the first collector 712, a first resistor 740, and/or a base of a bias transistor 705. The bias transistor 705 may comprise an NPN transistor. The first resistor 740, a second resistor 741, and/or a first voltage source 747 may be coupled to a second node 731. The second resistor 741, a third resistor 742, and/or a fourth resistor 743 may be coupled to a third node 732. The third resistor 742 may be directly coupled to the first base 716.

The bias transistor 705 may comprise a collector that may be coupled to a second voltage source 748. The bias transistor 705 may further comprise an emitter that may be coupled to a fifth resistor 744.

The second device 703 may comprise a second collector 713, a second emitter 715, and/or a second base 717. The second emitter 715 may be grounded and/or coupled to ground. The second base 717 may be directly coupled to the fifth resistor 744 and/or may be directly coupled to the emitter of the bias transistor 705. The second collector 713 may be directly coupled to a third voltage source 749.

The first device 702 may be situated as closely as possible the second device 703 to establish a thermal and/or heat transfer between the first device 702 and the second device 703. In some examples, the first device 702 and the second device 703 may be thermally linked. For example, heat generated at the second device 703 may be sensed at the first device 702 and/or heat generated at the first device 702 may be sensed at the second device 703. The thermal interaction between the first device 702 and the second device 703 may be manipulated in various ways to control gain vs. time response of the power amplifier.

The terms “thermally linked,” “thermal coupling,” and or similar terms are used herein according to their broad and ordinary meaning and may refer to a physical and/or non-physical connection between multiple devices wherein heating at one of the devices causes heating at another of the devices. Similarly, the term “thermally isolated” is used herein according to its broad and ordinary meaning and may refer to an absence of a physical and/or non-physical connection between multiple devices wherein heating at one of the devices does not cause heating at another of the devices.

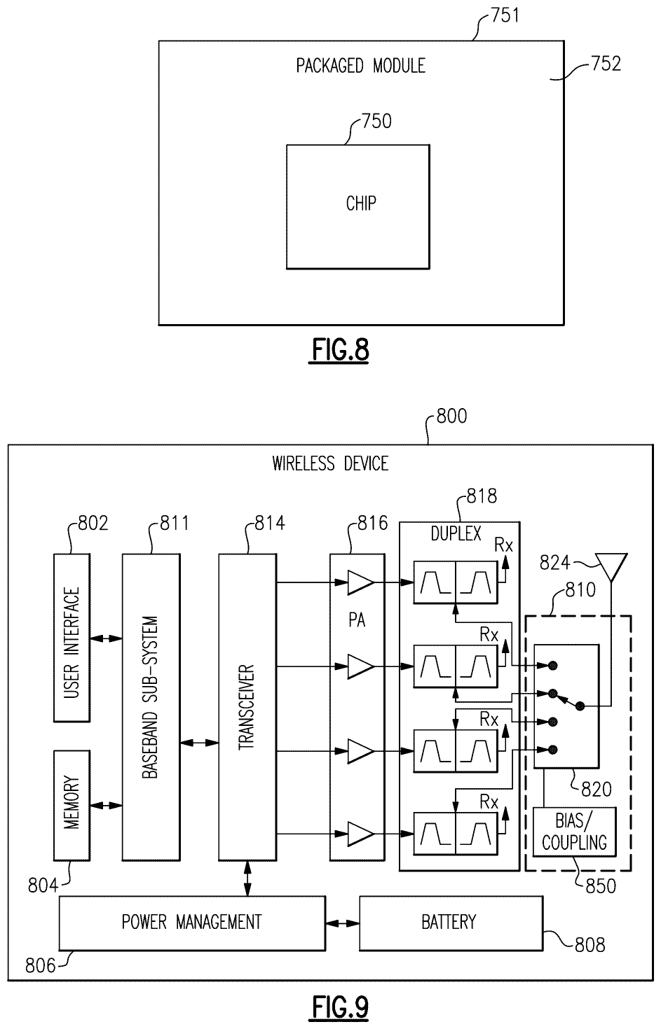

FIG. 8 shows that in some embodiments, one or more features as described herein can be implemented in a packaged module 751. Such a packaged module can include a packaging substrate 752 configured to receive a plurality of components. At least some of the components mounted on the packaging substrate 752 can include a flip chip device 750 such as one or more of the example flip chip devices described herein.

In some implementations, a device and/or a circuit having one or more features described herein can be included in an RF device such as a wireless device. Such a device and/or a circuit can be implemented directly in the wireless device, in a modular form as described herein, or in some combination thereof. In some embodiments, such a wireless device can include, for example, a cellular phone, a smart-phone, a hand-held wireless device with or without phone functionality, a wireless tablet, etc.

FIG. 9 depicts an example wireless device 800 having one or more advantageous features described herein. In some embodiments, a switching module 820 of a switching circuit 810 can include one or more RDL inductance as described herein.

In the example wireless device 800, a power amplifier (PA) assembly 816 having a plurality of PAs can provide one or more amplified RF signals to the switch 820 (via an assembly of one or more duplexers 818), and the switch 820 can route the amplified RF signal(s) to one or more antennas. The PAs 816 can receive corresponding unamplified RF signal(s) from a transceiver 814 that can be configured and operated in known manners. The transceiver 814 can also be configured to process received signals. The transceiver 814 is shown to interact with a baseband sub-system 811 that is configured to provide conversion between data and/or voice signals suitable for a user and RF signals suitable for the transceiver 814. The transceiver 814 is also shown to be connected to a power management component 806 that is configured to manage power for the operation of the wireless device 800 and/or that may be coupled to a battery 808. Such a power management component can also control operations of the baseband sub-system 811 and the module 820. The sub-system 811 may comprise a bias/coupling module 850.

The baseband sub-system 811 is shown to be connected to a user interface 802 to facilitate various input and output of voice and/or data provided to and received from the user. The baseband sub-system 811 can also be connected to a memory 804 that is configured to store data and/or instructions to facilitate the operation of the wireless device, and/or to provide storage of information for the user.

In some embodiments, the duplexers 818 can allow transmit and receive operations to be performed simultaneously using a common antenna (e.g., 824). In FIG. 9, received signals are shown to be routed to “Rx” paths that can include, for example, one or more low-noise amplifiers (LNAs).

A number of other wireless device configurations can utilize one or more features described herein. For example, a wireless device does not need to be a multi-band device. In another example, a wireless device can include additional antennas such as diversity antenna, and additional connectivity features such as Wi-Fi, Bluetooth, and GPS.

The present disclosure describes various features, no single one of which is solely responsible for the benefits described herein. It will be understood that various features described herein may be combined, modified, or omitted, as would be apparent to one of ordinary skill. Other combinations and sub-combinations than those specifically described herein will be apparent to one of ordinary skill, and are intended to form a part of this disclosure. Various methods are described herein in connection with various flowchart steps and/or phases. It will be understood that in many cases, certain steps and/or phases may be combined together such that multiple steps and/or phases shown in the flowcharts can be performed as a single step and/or phase. Also, certain steps and/or phases can be broken into additional sub-components to be performed separately. In some instances, the order of the steps and/or phases can be rearranged and certain steps and/or phases may be omitted entirely. Also, the methods described herein are to be understood to be open-ended, such that additional steps and/or phases to those shown and described herein can also be performed.

Unless the context clearly requires otherwise, throughout the description and the claims, the words “comprise,” “comprising,” and the like are to be construed in an inclusive sense, as opposed to an exclusive or exhaustive sense; that is to say, in the sense of “including, but not limited to.” The word “coupled,” as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Where the context permits, words in the above Detailed Description using the singular or plural number may also include the plural or singular number, respectively. The word “or” in reference to a list of two or more items, that word covers all of the following interpretations of the word: any of the items in the list, all of the items in the list, and any combination of the items in the list. The word “exemplary” is used exclusively herein to mean “serving as an example, instance, or illustration.” Any implementation described herein as “exemplary” is not necessarily to be construed as preferred or advantageous over other implementations.

The disclosure is not intended to be limited to the implementations shown herein. Various modifications to the implementations described in this disclosure may be readily apparent to those skilled in the art, and the generic principles defined herein may be applied to other implementations without departing from the spirit or scope of this disclosure. The teachings of the invention provided herein can be applied to other methods and systems, and are not limited to the methods and systems described above, and elements and acts of the various embodiments described above can be combined to provide further embodiments. Accordingly, the novel methods and systems described herein may be embodied in a variety of other forms; furthermore, various omissions, substitutions, and changes in the form of the methods and systems described herein may be made without departing from the spirit of the disclosure. The accompanying claims and their equivalents are intended to cover such forms or modifications as would fall within the scope and spirit of the disclosure.

What is claimed is:

1. A power amplifier circuit comprising:
a first transistor having a first collector, a first emitter, and a first base;
a second transistor having a second collector, a second emitter, and a second base, the second transistor being thermally linked to the first transistor; and
a bias transistor having a third collector, a third emitter, and a third base, the bias transistor being coupled between the first transistor and the second transistor.

2. The circuit of claim 1 wherein the first transistor comprises a first stage of the circuit and the second transistor comprises a second stage of the circuit.

3. The circuit of claim 1 wherein the first transistor and the second transistor are disposed less than 10 μm away from each other.

4. The circuit of claim 1 wherein first collector and the third base are coupled at a first node.

5. The circuit of claim 4 wherein the first collector is directly coupled to the third base.

6. The circuit of claim 4 wherein the third emitter is coupled to the second base.

7. The circuit of claim 6 wherein the third emitter is coupled to the second base via a first resistor.

8. The circuit of claim 6 wherein the third collector is coupled to a first voltage source.

9. The circuit of claim 6 wherein the first base and the third base are coupled to a first voltage source.

10. The circuit of claim 6 wherein the second collector is coupled to a first voltage source.

11. A semiconductor die of a power amplifier comprising:
a first transistor having a first collector, a first emitter, and a first base;
a second transistor having a second collector, a second emitter, and a second base, the second transistor being thermally linked to the first transistor; and
a bias transistor having a third collector, a third emitter, and a third base, the bias transistor being coupled between the first transistor and the second transistor.

12. The semiconductor die of claim 11 wherein the first transistor comprises a first stage of the power amplifier and the second transistor comprises a second stage of the power amplifier.

13. The semiconductor die of claim 11 wherein the first transistor and the second transistor are disposed less than 10 μm away from each other.

14. The semiconductor die of claim 11 wherein first collector and the third base are coupled at a first node.

15. The semiconductor die of claim 14 wherein the first collector is directly coupled to the third base.

16. The semiconductor die of claim 14 wherein the third emitter is coupled to the second base.

17. The semiconductor die of claim 16 wherein the third emitter is coupled to the second base via a first resistor.

18. The semiconductor die of claim 16 wherein the third collector is coupled to a first voltage source.

19. The semiconductor die of claim 16 wherein the first base and the third base are coupled to a first voltage source.

20. The semiconductor die of claim 16 wherein the second collector is coupled to a first voltage source.
